(19) United States
(12) Patent Application Publication
(10) Pub. No.: US 2025/0051915 A1
(43) Pub. Date: Feb. 13, 2025

(54) PLASMA PROCESSING METHOD AND PLASMA PROCESSING APPARATUS

(71) Applicant: Tokyo Electron Limited, Tokyo (JP)

(72) Inventors: Yuta NAKANE, Kurokawa-gun (JP); Sho Kumakura, Kurokawa-gun (JP)

(73) Assignee: Tokyo Electron Limited, Tokyo (JP)

(21) Appl. No.: 18/933,255

(22) Filed: Oct. 31, 2024

Related U.S. Application Data
(63) Continuation of application No. PCT/JP2023/016122, filed on Apr. 24, 2023.

(30) Foreign Application Priority Data
May 2, 2022 (JP) 2022-075745

(51) Int. Cl. C23C 16/455; C23C 16/505; H01J 37/32

(52) U.S. Cl. CPC C23C 16/45553; C23C 16/45536; C23C 16/505; H01J 37/32183; H01J 37/32449; H01J 37/32715

(57) ABSTRACT

A plasma processing method includes (a) providing a substrate including a first region including a first material and a second region including a second material different from the first material; (b) supplying a modifying gas for modifying a surface of the first region and a carbon-containing precursor; (c) forming a modified layer by modifying the surface of the first region with plasma generated from a gas mixture including the modifying gas and the carbon-containing precursor by supplying first radio frequency power; and (d) removing the modified layer in a manner that the modified layer and the carbon-containing precursor are caused to react with each other by stopping supply of the first radio frequency power or supplying second radio frequency power smaller than the first radio frequency power.

### CROSS-REFERENCE TO RELATED APPLICATIONS

This application is a continuation application of PCT Application No. PCT/JP2023/016122, filed on Apr. 24, 2023, which claims the benefit of priority from Japanese Patent Application No. 2022-075745, filed on May 2, 2022. The entire contents of the above listed PCT and priority applications are incorporated herein by reference.

### BACKGROUND

### Field

Example embodiments of the present disclosure relate to a plasma processing method and a plasma processing apparatus.

### Description of the Related Art

Japanese Unexamined Patent Publication No. 2018-26566 discloses an atomic layer etching (ALE) method. In this method, a substrate is exposed to a hydrogen fluoride gas to form a fluorinated surface layer on a metal oxide film. Then, the substrate is exposed to a boron-containing gas to remove the fluorinated surface layer from the metal oxide film.

### SUMMARY

In an example embodiment, a plasma processing method may include: (a) providing a substrate including a first region including a first material and a second region including a second material different from the first material; (b) supplying a modifying gas for modifying a surface of the first region and a carbon-containing precursor; (c) forming a modified layer by modifying the surface of the first region with plasma generated from a gas mixture including the modifying gas and the carbon-containing precursor by supplying first radio frequency power; and (d) removing the modified layer in a manner that the modified layer and the carbon-containing precursor are caused to react with each other by stopping supply of the first radio frequency power or supplying second radio frequency power smaller than the first radio frequency power.

The foregoing summary is illustrative only and is not intended to be in any way limiting. In addition to the illustrative aspects, example embodiments, and features described above, further aspects, example embodiments, and features will become apparent by reference to the drawings and the following detailed description.

### BRIEF DESCRIPTION OF THE DRAWINGS

FIG. 1 is a schematic diagram illustrating a plasma processing apparatus according to an example embodiment.

FIG. 2 is a schematic diagram illustrating a plasma processing apparatus according to an example embodiment.

FIG. 3 is a flowchart of a plasma processing method according to an example embodiment.

FIG. 4 is a cross-sectional view of an example of a substrate to which the method in FIG. 3 may be applied.

FIG. 5 is a cross-sectional view of an example of a substrate in a step of a plasma processing method according to an example embodiment.

FIG. 6 is a cross-sectional view of an example of a substrate in a step of a plasma processing method according to an example embodiment.

FIG. 7 is a cross-sectional view of an example of a substrate in a step of a plasma processing method according to an example embodiment.

FIG. 8 is a timing chart illustrating an example of a change in time of radio frequency power and bias power supplied to the plasma processing apparatus.

FIG. 9 is a timing chart illustrating another example of the change in time of the radio frequency power and the bias power supplied to the plasma processing apparatus.

FIG. 10 is a timing chart illustrating still another example of the change in time of the radio frequency power and the bias power supplied to the plasma processing apparatus.

FIG. 11 is a cross-sectional view illustrating an etching device included in a plasma processing apparatus according to an example embodiment.

FIG. 12 is a diagram illustrating a plasma processing apparatus according to an example embodiment.

### DETAILED DESCRIPTION

Hereinafter, various example embodiments (1) to (19) will be described.

Embodiment (1) A plasma processing method comprising:
(a) providing a substrate including a first region including a first material and a second region including a second material different from the first material;
(b) supplying a modifying gas for modifying a surface of the first region and a carbon-containing precursor;
(c) forming a modified layer by modifying the surface of the first region with plasma generated from a gas mixture including the modifying gas and the carbon-containing precursor by supplying first radio frequency power; and
(d) removing the modified layer in a manner that the modified layer and the carbon-containing precursor are caused to react with each other by stopping supply of the first radio frequency power or supplying second radio frequency power smaller than the first radio frequency power.

According to the plasma processing method, by controlling the supply of the radio frequency power, it is possible to perform switching between the formation of the modified layer and the removal of the modified layer. It is not necessary to purge the gas between (c) and (d). As a result, it is possible to obtain high productivity.

Embodiment (2) In the embodiment (1), the first region may include a metal-containing film, and the second region includes a mask. In this case, the metal-containing film can be etched by using a mask.

Embodiment (3) In the embodiment (1) or (2), the carbon-containing precursor may not contain metal. In this case, in (c), even though the carbon-containing precursor in the plasma is dissociated, the metal derived from the carbon-containing precursor is not generated, and thus it is possible to suppress metal contamination of the substrate.

Embodiment (4) In the embodiment (3), the carbon-containing precursor may include at least one of alcohol, β-diketone, amidine, acetamidine, or β-diketimine.

Embodiment (5) In any one of the embodiments (1) to (4), the modifying gas and the carbon-containing precursor may be continuously supplied in a period including (c) and (d). In this case, it is possible to continuously perform the formation of the modified layer and the removal of the modified layer.

Embodiment (6) In any one of the embodiments (1) to (5), the method may further comprise (e) repeating (c) and (d). In this case, it is possible to increase the etching amount of the first region.

Embodiment (7) In any one of the embodiments (1) to (6), the substrate may be heated in (d). In this case, it is possible to promote the reaction between the modified layer and the carbon-containing precursor.

Embodiment (8) In any one of the embodiments (1) to (7), the modifying gas may include at least one of a halogen-containing gas or an oxygen-containing gas.

Embodiment (9) In any one of the embodiments (1) to (8), the modifying gas may include at least one of a fluorine-containing gas or a chlorine-containing gas.

Embodiment (10) In any one of the embodiments (1) to (9), the modifying gas may include at least one selected from the group consisting of a fluorocarbon gas, an HF gas, an NF₃ gas, an SF₆ gas, a chlorocarbon gas, a Cl₂ gas, an NCl₃ gas, an SCl₆ gas, an O₂ gas, a CO gas, and a CO₂ gas.

Embodiment (11) In any one of the embodiments (1) to (10), in (d), the supply of the first radio frequency power may be stopped such that plasma is not generated.

Embodiment (12) In any one of the embodiments (1) to (11), a carbon-containing deposit may be formed on the second region in (c). In this case, it is possible to protect the second region by the carbon-containing deposit.

Embodiment (13) In any one of the embodiments (1) to (12), in (c), bias power may be supplied to an electrode in a substrate support that supports the substrate. In this case, since ions derived from the modifying gas in the plasma are attracted to the surface of the first region, the formation of the modified layer is promoted.

Embodiment (14) In the embodiment (13), a period in which the bias power is supplied may be shorter than a period in which the first radio frequency power is supplied. In this case, the formation of the carbon-containing deposit on the second region is promoted in a period in which the bias power is not supplied.

Embodiment (15) In the embodiment (13) or (14), the bias power may include first bias power and second bias power larger than the first bias power. In this case, the formation of the carbon-containing deposit on the second region is promoted in a period in which the first bias power is supplied. The formation of the modified layer is promoted in a period in which the second bias power is supplied. Embodiment (16) A plasma processing method comprising:
(a) providing a substrate including a metal-containing film and a mask on the metal-containing film;
(b) supplying a modifying gas for modifying a surface of the metal-containing film and a carbon-containing precursor;
(c) forming a modified layer by modifying the surface of the metal-containing film with plasma generated from a gas mixture including the modifying gas and the carbon-containing precursor by supplying first radio frequency power; and
(d) removing the modified layer in a manner that the modified layer and the carbon-containing precursor are caused to react with each other by stopping supply of the first radio frequency power.

Embodiment (17) A plasma processing method comprising:
(a) providing a substrate including a first region including metal and a second region including an element other than the metal, on a substrate support including an electrode;
(b) supplying a gas including at least one of halogen or oxygen and a carbon-containing precursor; and
(c) removing the first region, wherein
(c) includes
   (c1) a first period in which first radio frequency power is supplied, and
   (c2) a second period alternated with the first period, wherein the first radio frequency power is not supplied or second radio frequency power smaller than the first radio frequency power is supplied in the second period.

Embodiment (18) In the embodiment (17), the first radio frequency power and the second radio frequency power may be radio frequency power for plasma generation.

Embodiment (19) A plasma processing apparatus comprising:
a chamber;
a substrate support for supporting a substrate in the chamber, the substrate including a first region including a first material and a second region including a second material different from the first material;
a gas supply configured to supply a modifying gas for modifying a surface of the first region and a carbon-containing precursor in the chamber;
a plasma generator configured to generate plasma from a gas mixture including the modifying gas and the carbon-containing precursor by supplying first radio frequency power in the chamber; and
a controller, wherein
the controller is configured to control the gas supply and the plasma generator to
   form a modified layer by modifying the surface of the first region with the plasma, and
   remove the modified layer in a manner that the modified layer and the carbon-containing precursor are caused to react with each other by stopping supply of the first radio frequency power or supplying second radio frequency power smaller than the first radio frequency power.

Hereinafter, various example embodiments will be described in detail with reference to the drawings. In the drawing, the same or equivalent portions are denoted by the same reference symbols.

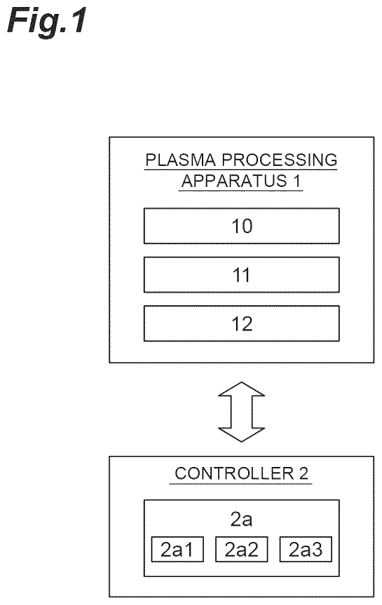

FIG. 1 illustrates an example configuration of a plasma processing system. In an embodiment, the plasma processing system includes a plasma processing apparatus 1 and a controller 2. The plasma processing system is an example substrate processing system, and the plasma processing apparatus 1 is an example substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2a1, a storage 2a2, and a communication interface 2a3. The controller 2 is implemented in, for example, a computer 2a. The processor 2a1 may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2a1 reads to execute the program from the storage 2a2. The medium may be of any type which can be accessed by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

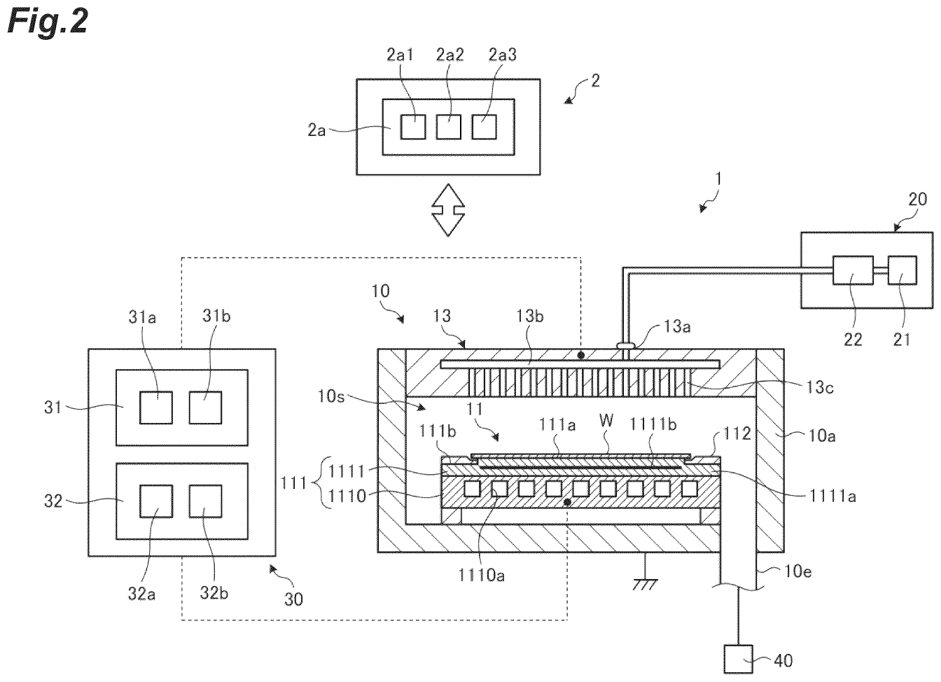

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, an electric power source 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in a plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The showerhead 13 and the substrate support 11 are electrically insulated from the housing of the plasma processing chamber 10. The substrate support 11 includes a body 111 and a ring assembly 112. The body 111 has a central region 111a for supporting a substrate W and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the ring assembly 112.

In an embodiment, the body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In an embodiment, the ceramic member 1111a also has the annular region 111b. Any other member, such as an annular electrostatic chuck or an annular insulting member, surrounding the electrostatic chuck 1111 may have the annular region 111b. In this case, the ring assembly 112 may be disposed on either the annular electrostatic chuck or the annular insulating member, or both the electrostatic chuck 1111 and the annular insulating member. At least one RF/DC electrode coupled to an RF source 31 and/or a DC source 32 described below may be disposed in the ceramic member 1111a. In this case, the at least one RF/DC electrode functions as the lower electrode. If a bias RF signal and/or DC signal described below are supplied to the at least one RF/DC electrode, the RF/DC electrode is also called a bias electrode. It is noted that the conductive member of the base 1110 and the at least one RF/DC electrode may each function as a lower electrode. The electrostatic electrode 1111b may also be function as a lower electrode. The substrate support 11 accordingly includes at least one lower electrode.

The ring assembly 112 includes one or more annular members. In an embodiment, the annular members include one or more edge rings and at least one cover ring. The edge ring is composed of a conductive or insulating material, whereas the cover ring is composed of an insulating material.

The substrate support 11 may also include a temperature adjusting module that is configured to adjust at least one of the electrostatic chuck 1111, the ring assembly 112, and the substrate to a target temperature. The temperature adjusting module may be a heater, a heat transfer medium, a flow passage 1110a, or any combination thereof. A heat transfer fluid, such as brine or gas, flows into the flow passage 1110a. In an embodiment, the flow passage 1110a is formed in the base 1110, one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include a flow modulation device that can modulate or pulse the flow of the at least one process gas.

The electric power source 30 include an RF source 31 coupled to the plasma processing chamber 10 through at least one impedance matching circuit. The RF source 31 is configured to supply at least one RF signal (RF power) to at least one lower electrode and/or at least one upper electrode. A plasma is thereby formed from at least one process gas supplied into the plasma processing space 10s. Thus, the RF source 31 can function as at least part of the plasma generator 12. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the at least one lower electrode and/or the at least one upper electrode through the at least one impedance matching circuit and is configured to generate a source RF signal (source RF power) for generating a plasma. In an embodiment, the source RF signal has a frequency in a range of 10 MHz to 150 MHZ. In an embodiment, the first RF generator 31a may be configured to generate two or more source RF signals having different frequencies. The resulting source RF signal(s) is supplied to the at least one lower electrode and/or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHZ. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the plasma processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses have rectangular, trapezoidal, or triangular waveform, or a combined waveform thereof. In an embodiment, a waveform generator for generating a sequence of voltage pulses from the DC signal is disposed between the first DC generator 32a and the at least one lower electrode. The first DC generator 32a and the waveform generator thereby functions as a voltage pulse generator. In the case that the second DC generator 32b and the waveform generator functions as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

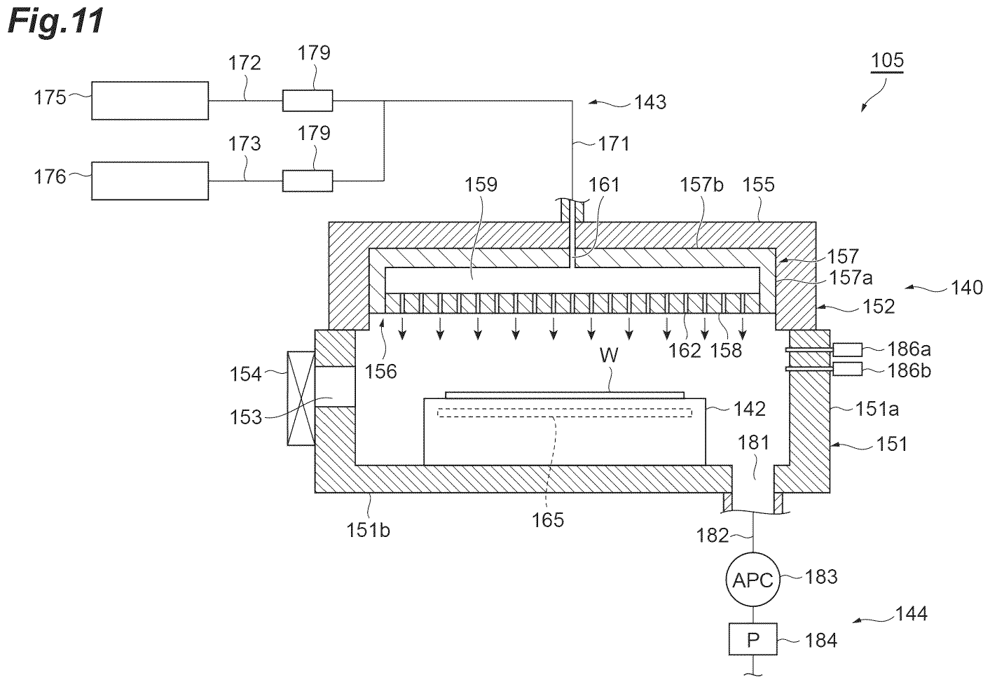

The plasma processing apparatus 1 may include a heating device for heating the surface of the substrate W. An etching device 105 illustrated in FIG. 11, which will be described later, may include a heating device for heating the surface of the substrate W. The heating device may include, for example, an energy ray generation device. Examples of the energy ray generation device include an infrared ray generation device, an electromagnetic wave generation device, and a laser generation device. The heating device may be provided outside the plasma processing chamber 10. In this case, for example, the surface of the substrate W can be heated by irradiating the substrate W with the energy ray through a window provided in the side wall 10a of the plasma processing chamber 10. Alternatively, the surface of the substrate W can be heated by irradiating the substrate W with the energy ray through the shower head 13 formed of a material having energy ray transmittance. The heating device may be provided in the plasma processing chamber 10. In this case, the heating device may include a heater provided in the substrate support 11.

The plasma processing apparatus 1 may include a monitor device that monitors the etching amount. The etching device 105 illustrated in FIG. 11, which will be described later, may include a monitor device that monitors the etching amount. The end point of the etching can be detected by the monitor device. The monitor device may be an optical emission spectrometer (OES) that analyzes plasma emission. The monitor device may be a film thickness meter that measures a thickness of a film to be etched. Examples of the film thickness meter include an optical film thickness meter. The film thickness meter may be a line-shaped film thickness meter. The film thickness meter may be provided outside the plasma processing chamber 10. In an example, the substrate W after etching may be provided on a transfer path on which the substrate W is transferred (for example, an opening portion formed in the chamber through which the substrate passes). The monitor device may be a mass measuring instrument that measures the mass of the substrate W. Examples of the mass measuring instrument include a scale. The mass measuring instrument may be provided below the substrate support 11.

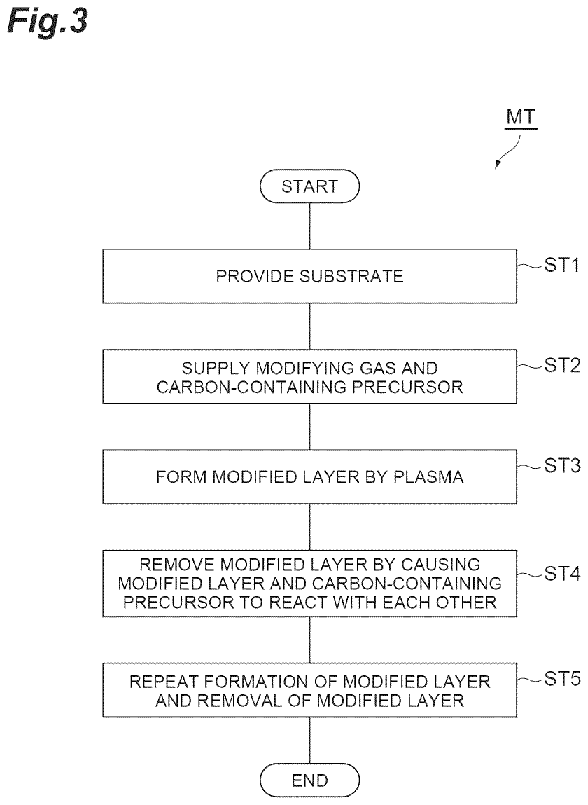

FIG. 3 is a flowchart of a plasma processing method according to an example embodiment. The plasma processing method MT (referred to as a “method MT” below) illustrated in FIG. 3 can be performed by the plasma processing apparatus 1 in the above embodiment. The method MT may be an etching method. The method MT may be an atomic layer etching (ALE) method. The method MT can be applied to a substrate W.

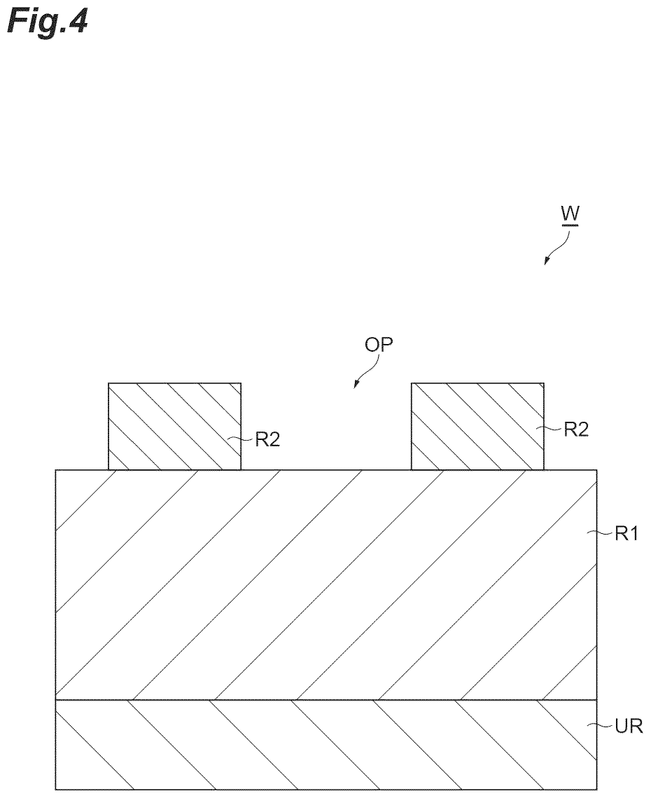

FIG. 4 is a cross-sectional view of an example of a substrate to which the method in FIG. 3 can be applied. As illustrated in FIG. 4, in an embodiment, the substrate W includes a first region RI1and a second region R2. The substrate W may include an underlying region UR. The first region R1 may be provided on the underlying region UR. The second region R2 may be provided on the first region R1.

The first region R1 includes a first material. The first region R1 may include metal. The first region R1 may include a metal-containing film. The first region R1 may include at least one of a metal film or a metal compound film. The first region R1 may include at least one of oxygen or nitrogen. The first region R1 may include at least one of a metal oxide or a metal nitride. The first region R1 may include at least one of Al, Hf, Zr, Fe, Ni, Co, Mn, Mg, Rh, Ru, Cr, Si, Ti, Ga, In, Zn, Pb, Ge, Ta, Cu, W, Mo, Pt, Cd, or Sn.

The second region R2 includes a second material different from the first material. The second region R2 may include an element (for example, metal, silicon, or carbon) other than the metal included in the first region R1. The second region R2 may include silicon. The second region R2 may include at least one of a silicon oxide or a silicon nitride. The second region R2 may include carbon. The second region R2 may include at least one of photoresist, spin-on carbon, amorphous carbon, or tungsten carbide. The second region R2 may include a mask. The second region R2 may have an opening OP.

The underlying region UR may include a third material different from the first material and the second material. The underlying region UR may include at least one of silicon, carbon, or metal.

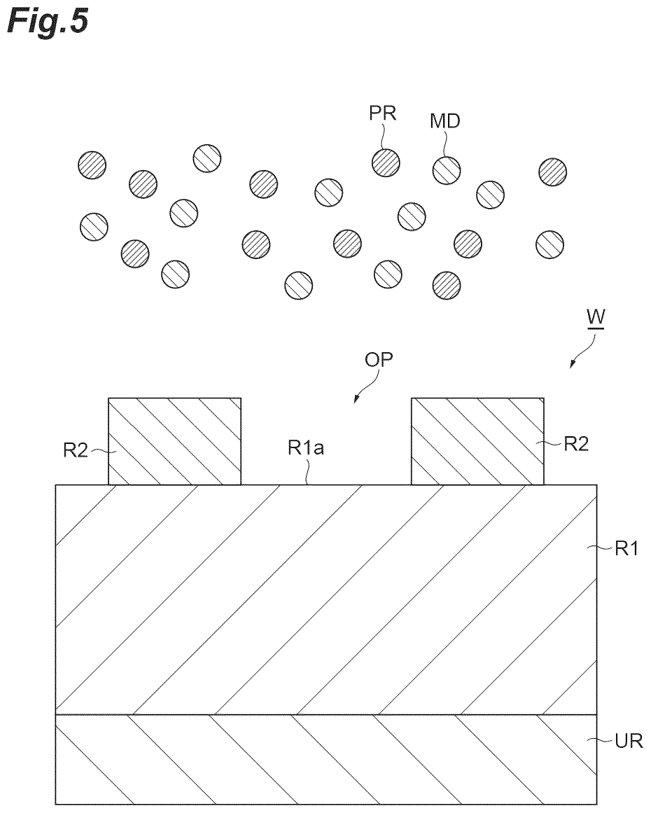

The method MT will be described with reference to FIGS. 3 to 7 by using, as an example, the case where the method MT is applied to the substrate W by using the plasma processing apparatus 1 in the above-described embodiment. FIGS. 5 to 7 are cross-sectional views of examples of a substrate in a step of the plasma processing method according to an example embodiment. When the plasma processing apparatus 1 is used, the method MT can be performed in the plasma processing apparatus 1 in a manner that the controller 2 controls each unit of the plasma processing apparatus 1. In the method MT, as illustrated in FIG. 2, the substrate W on a substrate support 11 (substrate support) disposed in a plasma processing chamber 10 is processed.

As illustrated in FIG. 3, the method MT may include Steps ST1 to ST5. Steps ST1 to ST5 may be executed in order. Step ST5 may not be executed. Steps ST3 to ST5 can be executed in a state where Step ST2 is executed. Steps ST1 to ST5 may be executed in-situ. That is, the method MT may be performed without taking the substrate W out of the plasma processing chamber 10.

In Step ST1, a substrate W illustrated in FIG. 4 is provided. The substrate W may be provided on the substrate support 11 in the plasma processing chamber 10, as illustrated in FIG. 2. The underlying region UR can be disposed between the substrate support 11 and the first region R1.

In Step ST2, as illustrated in FIG. 5, a modifying gas MD for modifying a surface Ra1 of the first region R1 and a carbon-containing precursor PR are supplied. As illustrated in FIG. 2, the modifying gas MD and the carbon-containing precursor PR can be supplied from the gas supply 20 into the plasma processing chamber 10. The modifying gas MD and the carbon-containing precursor PR may be mixed in the plasma processing chamber 10 or may be mixed before being supplied into the plasma processing chamber 10. The modifying gas MD and the carbon-containing precursor PR may be supplied into the plasma processing chamber 10 at the same time or with a time difference.

The modifying gas MD may include at least one of a halogen-containing gas or an oxygen-containing gas. The halogen-containing gas can be used when the first region R1 includes at least one of a metal oxide film or a metal nitride film. The modifying gas MD may include a fluorine-containing gas. The fluorine-containing gas may include at least one of a hydrogen fluoride gas (HF gas), a fluorocarbon gas, a nitrogen-containing gas, or a sulfur-containing gas. The fluorocarbon gas may include at least one of a C₄F₆ gas, a C₄F₈ gas, a C₃F₈ gas, or a CF₄ gas. The nitrogen-containing gas may include an NF₃ gas. The sulfur-containing gas may include an SF₆ gas. The modifying gas MD may include a chlorine-containing gas. The chlorine-containing gas may include at least one of a Cl₂ gas, a chlorocarbon gas, a nitrogen-containing gas, or a sulfur-containing gas. The chlorocarbon gas may include at least one of a C₄Cl₆ gas, a C₃Cl₈ gas, a C₃Cl₈ gas, or a CCl₄ gas. The nitrogen-containing gas may include an NCl₃ gas. The sulfur-containing gas may include an SCl₆ gas.

The oxygen-containing gas can be used when the first region R1 includes a metal film. The oxygen-containing gas can include at least one of a O₂ gas, a CO gas, or a CO₂ gas.

The carbon-containing precursor PR may not contain a metal. The carbon-containing precursor PR may include at least one of alcohol, β-diketone, amidine, acetamidine, or β-diketimine. β-diketone may include at least one of acac (acetylacetone), hfac (hexafluoroacetylacetone), tfac (trifluoroacetylacetone), or tmhd (tetramethylheptanedione).

In Step ST2, an inert gas may be further supplied. The inert gas can include at least one of a noble gas or a N₂ gas.

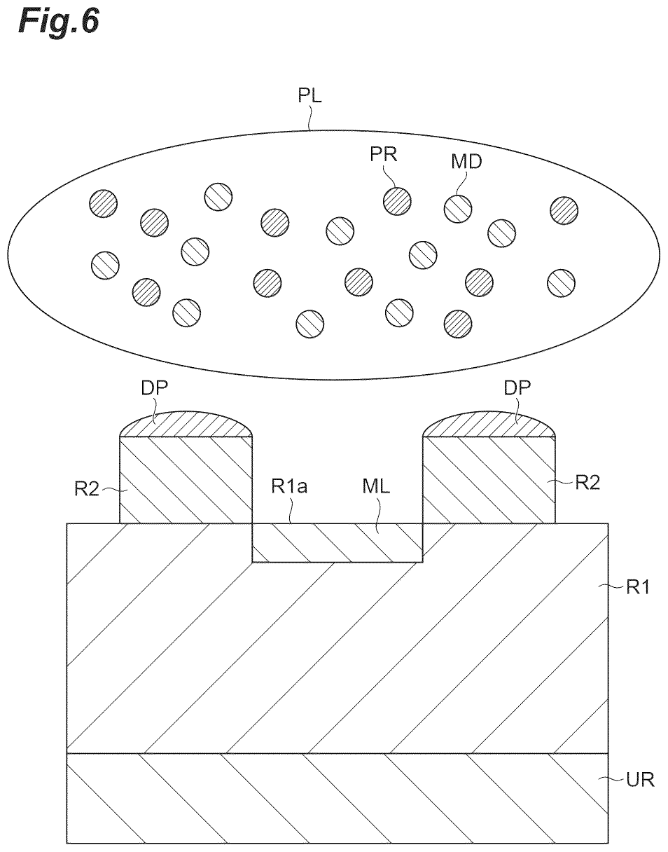

In Step ST3, as illustrated in FIG. 6, a modified layer ML is formed by modifying the surface R1a of the first region R1 with plasma PL generated from a gas mixture including the modifying gas MD and the carbon-containing precursor PR. The plasma PL is generated by supplying first radio frequency power to the plasma processing apparatus 1. In the plasma PL, the modifying gas MD is dissociated to generate active species (ions or radicals).

The modified layer ML can be formed by a reaction between the active species generated from the modifying gas MD and the first region R1. For example, the modifying gas MD may include a halogen-containing gas, and the first region R1 may include at least one of a metal oxide film or a metal nitride film. In this case, the modified layer ML can be formed by a reaction between the active species including halogen, which is generated from the modifying gas MD, and at least one of the metal oxide film or the metal nitride film.

In Step ST3, a carbon-containing deposit DP may be formed on the second region R2. The carbon-containing deposit DP can be formed from the carbon-containing precursor PR. In the plasma PL, the carbon-containing precursor PR is dissociated to generate active species (ions or radicals). The active species, which is generated from the carbon-containing precursor PR and includes carbon, is deposited on the second region R2, whereby the carbon-containing deposit DP can be formed. Since the second region R2 can be protected by the carbon-containing deposit DP, a high etching selectivity with respect to the second region R2 can be obtained in Step ST4.

In Step ST3, bias power may be supplied to an electrode in the substrate support 11 that supports the substrate W. The bias power can be radio frequency power. Since ions derived from the modifying gas MD in the plasma PL are attracted to the surface R1a of the first region R1 by the bias power, the formation of the modified layer ML is promoted.

In Step ST3, the substrate W may be heated. The temperature of the substrate support 11 may be 100° C. or higher, 150° C. or higher, or 200° C. or higher. The temperature of the substrate support 11 may be 450° C. or lower. The heating may be performed by the plasma PL generated in the plasma processing chamber 10 or the temperature adjusting module in the substrate support 11. The heating may be performed by an energy ray emitted from an energy ray generation device. The reaction between the first region R1 and the modifying gas MD is promoted by heating.

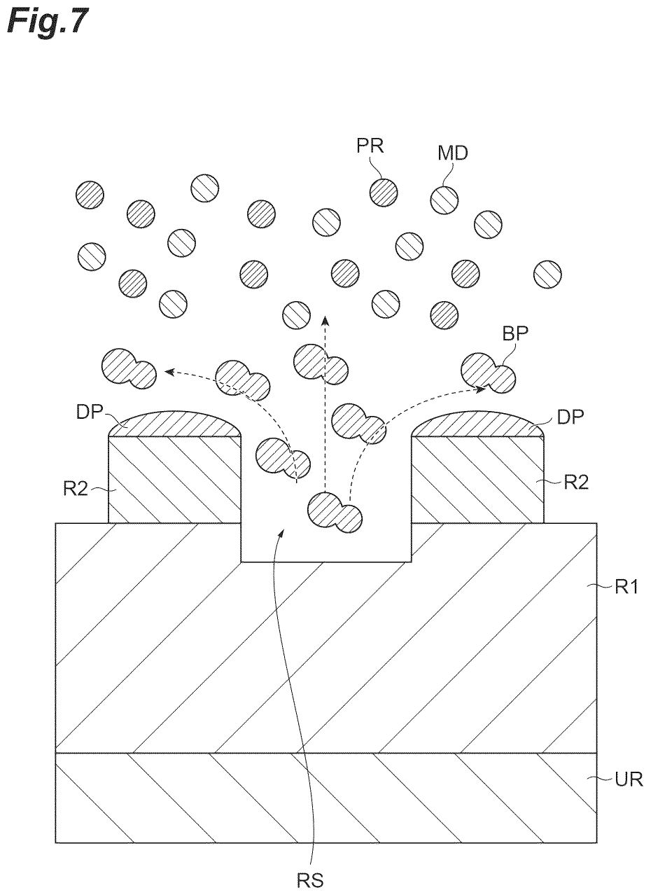

In Step ST4, as illustrated in FIG. 7, the modified layer ML is removed by stopping the supply of the first radio frequency power and causing the modified layer ML and the carbon-containing precursor PR to react with each other. With Steps ST3 and ST4, the first region R1 can be removed. The supply of the first radio frequency power may be stopped so that plasma is not generated. In Step ST4, a by-product BP having high volatility may be generated by the reaction between the modified layer ML and the carbon-containing precursor PR. The modified layer ML can be removed by volatilizing the by-product BP. By removing the modified layer ML, a recess portion RS can be formed in the first region R1. In Step ST4, second radio frequency power smaller than the first radio frequency power may be supplied. Even in this case, the by-product BP can be generated by the reaction between the modified layer ML and the carbon-containing precursor PR. The plasma may be generated by supplying the second radio frequency power. In this case, the by-product BP can be generated by the reaction between the carbon-containing precursor PR that is not dissociated in the plasma and the modified layer ML.

In Step ST4, the gas mixture including the modifying gas MD and the carbon-containing precursor PR may be supplied. In Step ST4, the supply of the modifying gas MD may be stopped, or the modifying gas MD having a flow rate smaller than the flow rate of the modifying gas MD in Step ST3 may be supplied.

In Step ST4, similarly to Step ST3, the substrate W may be heated. The reaction between the modified layer ML and the carbon-containing precursor PR is promoted by heating.

The modifying gas MD and the carbon-containing precursor PR may be continuously supplied in a period including Steps ST3 and ST4. That is, switching of the gas species and the purging of the gas may not be performed between Step ST3 and Step ST4. In the period including Steps ST3 and ST4, the flow rates of the modifying gas MD and the carbon-containing precursor PR may be constant or may be changed with time.

In Step ST5, Steps ST3 and ST4 may be repeated. Steps ST3 and ST4 can be executed alternately. Steps ST3 and ST4 may be repeated a plurality of times. Step ST5 may be ended when the number of times of executing Steps ST3 and ST4 reaches a threshold value. With Step ST5, it is possible to increase the etching amount of the first region R1, and thus it is possible to form a deep recess portion RS.

According to the method MT, the supply of the radio frequency power is controlled in Steps ST3 and ST4, so that the formation of the modified layer ML and the removal of the modified layer ML can be switched. It is not necessary to switch the gas species from the modifying gas MD to the carbon-containing precursor PR and to purge the gas (to remove the modifying gas MD) between Step ST3 and Step ST4. As a result, it is possible to shorten the total processing time of Steps ST3 and ST4, and thus it is possible to obtain high productivity.

When the carbon-containing precursor PR does not contain metal, even in a case where the carbon-containing precursor PR in the plasma PL is dissociated in Step ST3, metal derived from the carbon-containing precursor PR is not generated. As a result, it is possible to suppress the metal contamination of the substrate W and the plasma processing chamber 10.

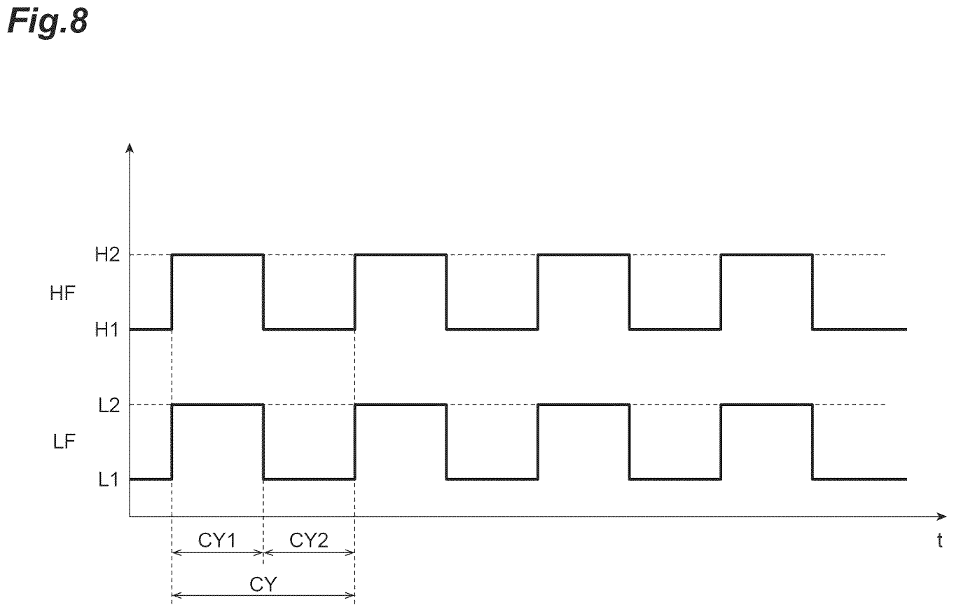

FIG. 8 is a timing chart illustrating an example of a change in time of the radio frequency power and the bias power supplied to the plasma processing apparatus. The horizontal axis indicates time t. The vertical axis indicates the magnitude of the power. The timing chart in FIG. 8 is related to Steps ST3 to ST5 in the method MT. The radio frequency power for generating the plasma PL in Step ST3 may be radio frequency power HF applied to the electrode in the body portion 111 of the substrate support 11 or the electrode facing the substrate support 11. The frequency of the radio frequency power HF may be 27 MHz or higher and 100 MHz or lower. The bias power may be radio frequency power LF applied to the electrodes in the body portion 111 of the substrate support 11. The frequency of the radio frequency power LF may be lower than the frequency of the radio frequency power HF. The frequency of the radio frequency power LF may be 100 kHz or higher and 40.68 MHz or lower.

The radio frequency power HF and the radio frequency power LF may be periodically applied at a cycle CY. That is, each of the radio frequency power HF and the radio frequency power LF may be a pulse. The cycle CY may include a first period CY1 and a second period CY2. The second period CY2 is a period after the first period CY1. The second period CY2 may be a period alternated with the first period CY1. The first period CY1 corresponds to Step ST3. In the first period CY1, the radio frequency power HF for generating the plasma PL may be supplied. The second period CY2 corresponds to Step ST4. In the second period CY2, the radio frequency power HF may not be supplied, or the radio frequency power HF for generating the plasma PL may be supplied. The radio frequency power HF that can be supplied in the second period CY2 is smaller than the radio frequency power HF supplied in the first period CY1. One cycle corresponding to the cycle CY may be repeated twice or more. A step of repeating the cycle CY corresponds to Step ST5. The frequency defining the cycle CY may be 0.1 Hz or higher and 100 kHz or lower, or may be 10 Hz or higher and 100 kHz or lower. The time length of the cycle CY is the reciprocal of the frequency defining the cycle CY.

In the first period CY1, the radio frequency power LF can be maintained at high power L2, and the radio frequency power HF can be maintained at high power H2. In the first period CY1, the modified layer ML and the carbon-containing deposit DP can be formed. In the second period CY2, the radio frequency power LF can be maintained at low power L1 (for example, 0 W) smaller than the high power L2, and the radio frequency power HF can be maintained at low power H1 (for example, 0 W) smaller than the high power H2. In the second period CY2, the modified layer ML and the carbon-containing deposit DP are not formed, and the modified layer ML can be removed. In FIG. 8, the radio frequency power HF and the radio frequency power LF may be synchronized pulses.

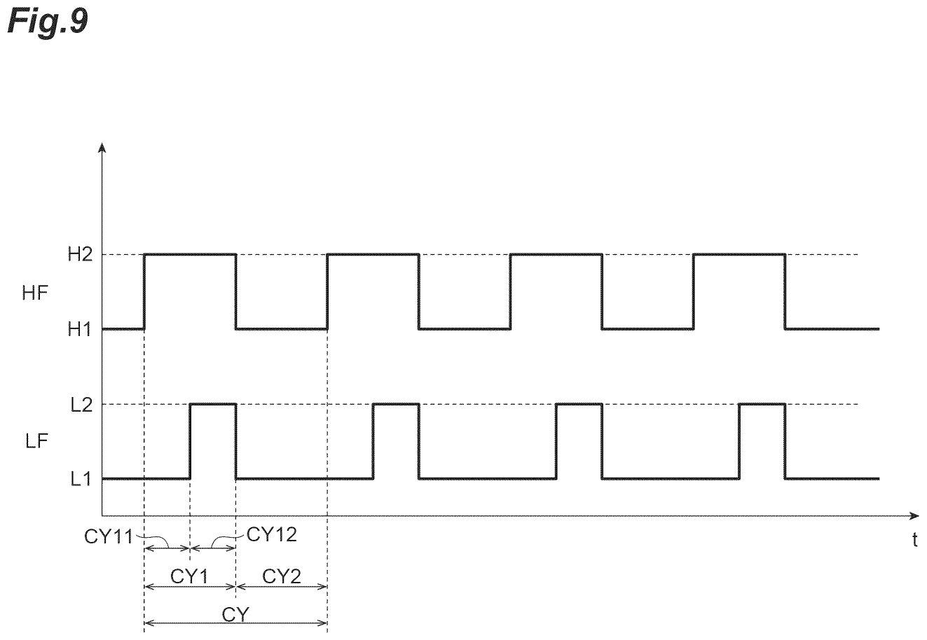

FIG. 9 is a timing chart illustrating another example of the change in time of the radio frequency power and the bias power supplied to the plasma processing apparatus. The timing chart in FIG. 9 is the same as the timing chart in FIG. 8 except that the power of the radio frequency power LF in the first period CY1 is different. In the timing chart in FIG. 9, the first period CY1 of the cycle CY can include a third period CY11 and a fourth period CY12. The fourth period CY12 is a period after the third period CY11.

In the third period CY11, the radio frequency power LF can be maintained at the low power L1, and the radio frequency power HF can be maintained at the high power H2. In the third period CY11, the formation of the carbon-containing deposit DP is promoted. In the fourth period CY12, the radio frequency power LF can be maintained at high power L2, and the radio frequency power HF can be maintained at high power H2. In the fourth period CY12, the formation of the modified layer ML is promoted. As described above, the fourth period CY12, which is the period in which the radio frequency power LF is supplied, may be shorter than the first period CY1, which is the period in which the radio frequency power HF is supplied.

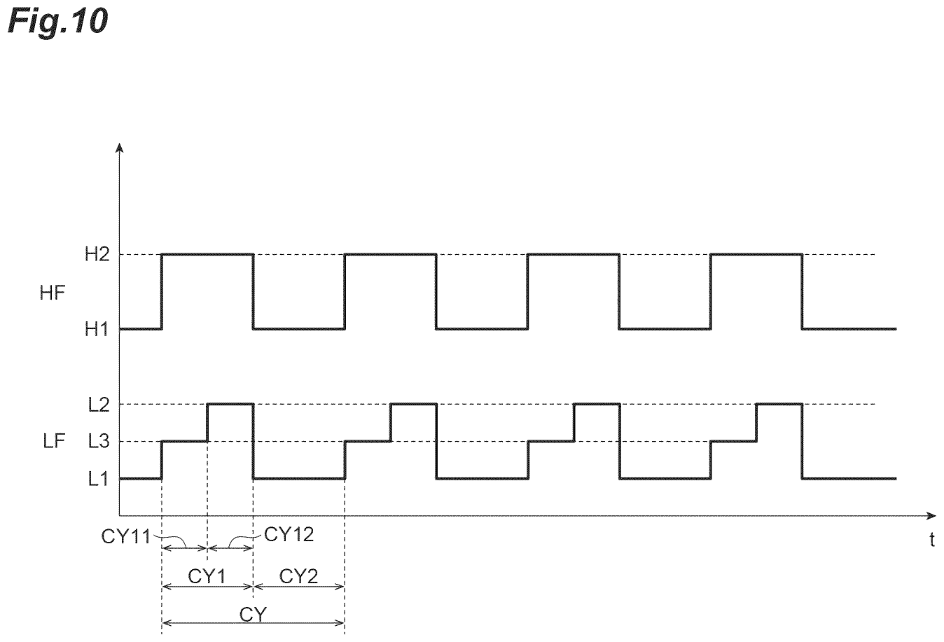

FIG. 10 is a timing chart illustrating still another example of the change in time of the radio frequency power and the bias power supplied to the plasma processing apparatus. The timing chart in FIG. 10 is the same as the timing chart in FIG. 9 except that the power of the radio frequency power LF in the third period CY11 is different. In the timing chart in FIG. 10, in the third period CY11, the radio frequency power LF can be maintained at medium power L3 (first bias power), and the radio frequency power HF can be maintained at the high power H2. The medium power L3 can be power between the low power L1 and the high power L2. In the third period CY11, the formation of the carbon-containing deposit DP is promoted. In the fourth period CY12, the radio frequency power LF is maintained at the high power L2 (second bias power).

The timing charts in FIGS. 8 to 10 may be changed as follows.

The radio frequency power HF may be maintained at the high power H2 in a part of the first period CY1 and may be maintained at power that is different from the high power H2 and is larger than the low power L1, in the other part of the first period CY1.

In the cycle CY, the ratio (the duty ratio of the radio frequency power HF) of the period in which the radio frequency power HF is maintained at the high power H2 may be changed. Similarly, in the cycle CY, the ratio (the duty ratio of the radio frequency power LF) of the period in which the radio frequency power LF is maintained at the high power L2 may be changed. The duty ratio of the radio frequency power HF and the radio frequency power LF may be adjusted such that almost the entirety of the modified layer ML formed in Step ST3 is removed in Step ST4.

As time elapses, at least one of the high power H2, the high power L2, the duty ratio of the radio frequency power HF, the duty ratio of the radio frequency power LF, the frequency defining the cycle CY of the radio frequency power HF, or the frequency defining the cycle CY of the radio frequency power LF may be changed. For example, as time elapses, the high power L2 and the high power H2 may be increased, or the frequency defining the cycle CY of the radio frequency power LF may be reduced.

FIG. 11 is a cross-sectional view illustrating an etching device included in a plasma processing apparatus according to an example embodiment. The plasma processing apparatus may include an etching device 105 illustrated in FIG. 11. The etching device 105 includes a chamber 140. Plasma is not generated in the chamber 140. A substrate support 142 for supporting the substrate W is provided in the chamber 140. The etching device 105 includes a gas supply 143 for supplying a gas into the chamber 140, and an exhaust system 144 for reducing the pressure in the chamber 140.

The chamber 140 includes a chamber body 151 and a lid portion 152. The chamber body 151 has a side wall portion 151a and a bottom portion 151b. The upper part of the chamber body 151 has an opening. The opening is closed by the lid portion 152. The side wall portion 151a and the bottom portion 151b are sealed by a sealing member.

The lid portion 152 includes a lid member 155 located outside and a shower head 156 fitted to the inside of the lid member 155. The shower head 156 is provided to face the substrate support 142. The shower head 156 includes a body 157 and a shower plate 158. The body 157 has, for example, a cylindrical side wall 157a and an upper wall 157b. The shower plate 158 is provided at a bottom portion of the body 157. A space 159 is formed between the body 157 and the shower plate 158.

A gas introduction path 161 that penetrates up to the space 159 is formed in the lid member 155 and the upper wall 157b. A gas supply pipe 171 of the gas supply 143 is connected to the gas introduction path 161.

A plurality of gas discharge holes 162 are formed in the shower plate 158. The gas introduced into the space 159 through the gas supply pipe 171 and the gas introduction path 161 is discharged from the gas discharge hole 162 into the space in the chamber 140.

A gate 153 for transferring the substrate W between the space in the chamber 140 and the space outside the chamber 140 is provided on the side wall portion 151a. The gate 153 can be opened and closed by a gate valve 154.

The substrate support 142 is connected to the bottom portion 151b of the chamber 140. A temperature adjustor 165 for adjusting the temperature of the substrate support 142 is provided in the substrate support 142. The temperature adjustor 165 includes, for example, a pipe for causing a temperature adjusting medium such as water to flow. The temperature of the substrate support 142 is adjusted by performing heat exchange between the temperature adjusting medium flowing in the pipe and the outer portion of the pipe. As a result, the temperature of the substrate W on the substrate support 142 is controlled.

The gas supply 143 includes a first gas supply source 175 that supplies a first gas and a second gas supply source 176 that supplies a second gas. The first gas is, for example, the modifying gas MD. The second gas is, for example, the carbon-containing precursor PR. One end of a first gas supply pipe 172 is connected to the first gas supply source 175. The other end of the first gas supply pipe 172 is connected to the gas supply pipe 171. One end of a second gas supply pipe 173 is connected to the second gas supply source 176. The other end of the second gas supply pipe 173 is connected to the gas supply pipe 171. Each of the first gas supply pipe 172 and the second gas supply pipe 173 is provided with a flow rate controller 179 that performs an opening/closing operation of a flow passage and flow rate control.

Thus, the first gas is supplied from the first gas supply source 175 to the shower head 156 through the first gas supply pipe 172. The second gas is supplied from the second gas supply source 176 to the shower head 156 through the second gas supply pipe 173. These gases are discharged from the gas discharge holes 162 of the shower head 156 toward the substrate W in the chamber 140.

The exhaust system 144 has an exhaust pipe 182 connected to an exhaust port 181 formed in the bottom portion 151b of the chamber 140. The exhaust system 144 has an automatic pressure controller (APC) 183 and a vacuum pump 184 provided in the exhaust pipe 182. The automatic pressure controller 183 can control the pressure in the chamber 140. The vacuum pump 184 can discharge the gas in the chamber 140 to the outside of the chamber 140.

Two capacitance manometers 186a and 186b are provided on the side wall of the chamber 140 as pressure gauges for measuring the pressure in the chamber 140. The capacitance manometers 186a and 186b penetrate the side wall of the chamber 140. The capacitance manometer 186a can measure high pressure. The capacitance manometer 186b can measure low pressure. A temperature sensor that detects the temperature of the substrate W may be provided near the substrate W on the substrate support 142.

The gate 153 of the chamber 140 of the etching device 105 may be connected to a vacuum transfer module (VTM). The plasma processing chamber 10 of the plasma processing apparatus 1 in FIG. 2 may be connected to the vacuum transfer module. As a result, the substrate W can be transferred between the chamber 140 of the etching device 105 and the plasma processing chamber 10 of the plasma processing apparatus 1 while maintaining a decompressed state.

In the method MT, Step ST3 may be performed in the plasma processing chamber 10 of the plasma processing apparatus 1 in FIG. 2. Thereafter, the substrate W may be transferred by the vacuum transfer module, and Step ST4 may be executed in the chamber 140 of the etching device 105 in FIG. 11.

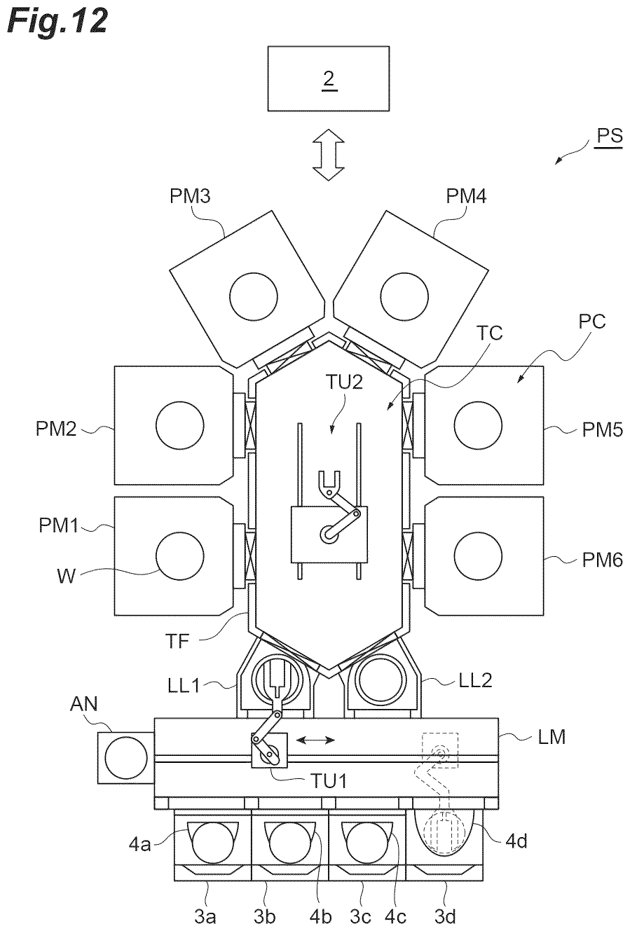

FIG. 12 is a diagram illustrating a plasma processing apparatus according to an example embodiment. A plasma processing apparatus PS illustrated in FIG. 12 may be used to perform the method MT.

The plasma processing apparatus PS includes stages 3a to 3d, containers 4a to 4d, a loader module LM, an aligner AN, load lock modules LL1 and LL2, process modules PM1 to PM6, a transfer module TF, and a controller 2. The number of stages, the number of containers, and the number of load lock modules in the plasma processing apparatus PS can be any number of one or more. Further, the number of process modules in the plasma processing apparatus PS may be any number of two or more.

The stages 3a to 3d are arranged along one edge of the loader module LM. The containers 4a to 4d are mounted on the stages 3a to 3d, respectively. Each of the containers 4a to 4d is, for example, a container called a front opening unified pod (FOUP). Each of the containers 4a to 4d is configured to accommodate the substrate W inside.

The loader module LM has a chamber. A pressure in the chamber of the loader module LM is set to an atmospheric pressure. The loader module LM has a transfer device TU1. The transfer device TU1 is, for example, an articulated robot and is controlled by the controller 2. The transfer device TU1 is configured to transfer the substrate W through a chamber of the loader module LM. The transfer device TU1 can transfer the substrate W between each of the containers 4a to 4d and the aligner AN, between the aligner AN and each of the load lock modules LL1 and LL2, and between each of the load lock modules LL1 and LL2, and each of the containers 4a to 4d. The aligner AN is connected to the loader module LM. The aligner AN is configured to perform adjustment of the position (calibration of the position) of the substrate W.

Each of the load lock module LL1 and the load lock module LL2 is provided between the loader module LM and the transfer module TF. Each of the load lock module LL1 and the load lock module LL2 provides a preliminary decompression chamber.

The transfer module TF is connected to each of the load lock module LL1 and the load lock module LL2 through a gate valve. The transfer module TF has a transfer chamber TC capable of being depressurized. The transfer module TF has a transfer device TU2. The transfer device TU2 is, for example, an articulated robot, and is controlled by the controller 2. The transfer device TU2 is configured to transfer the substrate W through a transfer chamber TC. The transfer device TU2 can transfer the substrate W between each of the load lock modules LL1 and LL2 and each of the process modules PM1 to PM6, and between any two process modules among the process modules PM1 to PM6.

Each of the process modules PM1 to PM6 is a processing apparatus configured to perform dedicated substrate processing. One process module among the process modules PM1 to PM6 may be the plasma processing chamber 10 in FIG. 2. Another one process module among the process modules PMI to PM6 may be the chamber 140 in FIG. 11. One process module among the process modules PM1 to PM6 may include a film thickness meter as a monitor device that monitors the etching amount. Alternatively, the transfer module TF may include a film thickness meter. In this case, the etching amount can be measured while the substrate W is transferred from one process module to another process module.

In the plasma processing apparatus PS, the controller 2 is configured to control each unit of the plasma processing apparatus PS. The plasma processing apparatus PS can transfer the substrate W between the process modules without bringing the substrate W into contact with the atmosphere.

Although the various example embodiments have been described above, various additions, omissions, substitutions, and changes may be made without being limited to the example embodiments described above. Other embodiments can be formed by combining elements in different embodiments.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing method comprising:
(a) providing a substrate including a first region including a first material and a second region including a second material different from the first material;
(b) supplying a modifying gas for modifying a surface of the first region and a carbon-containing precursor;
(c) forming a modified layer by modifying the surface of the first region with plasma generated from a gas mixture including the modifying gas and the carbon-containing precursor by supplying first radio frequency power; and
(d) removing the modified layer in a manner that the modified layer and the carbon-containing precursor are caused to react with each other by stopping supply of the first radio frequency power or supplying second radio frequency power smaller than the first radio frequency power.

2. The plasma processing method according to claim 1, wherein the first region includes a metal-containing film, and the second region includes a mask.

3. The plasma processing method according to claim 1, wherein the carbon-containing precursor does not contain metal.

4. The plasma processing method according to claim 3, wherein the carbon-containing precursor includes at least one of alcohol, β-diketone, amidine, acetamidine, or β-diketimine.

5. The plasma processing method according to claim 1, wherein the modifying gas and the carbon-containing precursor are continuously supplied in a period including (c) and (d).

6. The plasma processing method according to claim 1, further comprising:
(e) repeating (c) and (d).

7. The plasma processing method according to claim 1, wherein the substrate is heated in (d).

8. The plasma processing method according to claim 1, wherein the modifying gas includes at least one of a halogen-containing gas or an oxygen-containing gas.

9. The plasma processing method according to claim 1, wherein the modifying gas includes at least one of a fluorine-containing gas or a chlorine-containing gas.

10. The plasma processing method according to claim 1, wherein the modifying gas includes at least one selected from the group consisting of a fluorocarbon gas, an HF gas, an NF₃ gas, an SF₆ gas, a chlorocarbon gas, a Cl₂ gas, an NCl₃ gas, an SCl₆ gas, an O₂ gas, a CO gas, and a CO₂ gas.

11. The plasma processing method according to claim 1, wherein, in (d), the supply of the first radio frequency power is stopped such that plasma is not generated.

12. The plasma processing method according to claim 1, wherein a carbon-containing deposit is formed on the second region in (c).

13. The plasma processing method according to claim 1, wherein, in (c), bias power is supplied to an electrode in a substrate support that supports the substrate.

14. The plasma processing method according to claim 13, wherein a period in which the bias power is supplied is shorter than a period in which the first radio frequency power is supplied.

15. The plasma processing method according to claim 13, wherein the bias power includes first bias power and second bias power larger than the first bias power.

16. A plasma processing method comprising:
(a) providing a substrate including a metal-containing film and a mask on the metal-containing film;
(b) supplying a modifying gas for modifying a surface of the metal-containing film and a carbon-containing precursor;
(c) forming a modified layer by modifying the surface of the metal-containing film with plasma generated from a gas mixture including the modifying gas and the carbon-containing precursor by supplying first radio frequency power; and
(d) removing the modified layer in a manner that the modified layer and the carbon-containing precursor are caused to react with each other by stopping supply of the first radio frequency power.

17. A plasma processing method comprising:
(a) providing a substrate including a first region including metal and a second region including an element other than the metal, on a substrate support including an electrode;
(b) supplying a gas including at least one of halogen or oxygen and a carbon-containing precursor; and
(c) removing the first region, wherein
(c) includes
(c1) a first period in which first radio frequency power is supplied, and
(c2) a second period alternated with the first period, wherein the first radio frequency power is not supplied or second radio frequency power smaller than the first radio frequency power is supplied in the second period.

18. The plasma processing method according to claim 17, wherein the first radio frequency power and the second radio frequency power are radio frequency power for plasma generation.

19. A plasma processing apparatus comprising:
a chamber;
a substrate support for supporting a substrate in the chamber, the substrate including a first region including a first material and a second region including a second material different from the first material;
a gas supply configured to supply a modifying gas for modifying a surface of the first region and a carbon-containing precursor in the chamber;
a plasma generator configured to generate plasma from a gas mixture including the modifying gas and the carbon-containing precursor by supplying first radio frequency power in the chamber; and
a controller, wherein
the controller is configured to control the gas supply and the plasma generator to
form a modified layer by modifying the surface of the first region with the plasma, and
remove the modified layer in a manner that the modified layer and the carbon-containing precursor are caused to react with each other by stopping supply of the first radio frequency power or supplying second radio frequency power smaller than the first radio frequency power.
